(19) United States
(12) Patent Application Publication
(10) Pub. No.: US 2026/0258543 A1
(43) Pub. Date: Sep. 3, 2026

(54) MEMBER FOR PLASMA PROCESSING APPARATUS AND METHOD FOR MANUFACTURING THE SAME

(71) Applicant: Hitachi High-Tech Corporation, Minato-ku, Tokyo (JP)

(72) Inventors: Kazuhiro UEDA, Tokyo (JP); Kazuyuki IKENAGA, Tokyo (JP)

(21) Appl. No.: 18/841,495

(22) PCT Filed: Jul. 28, 2023
(86) PCT No.: PCT/JP2023/027802

§ 371 Date: Aug. 26, 2024

(51) Int. Cl. C23C 4/134; C23C 4/06; C23C 4/10; H01J 37/32

(52) U.S. Cl. CPC C23C 4/134; C23C 4/06; C23C 4/10; H01J 37/32495

(57) ABSTRACT

The coating film 53 is formed on the base material 52 of a member for a plasma processing apparatus using a suspension plasma spraying method. The suspension liquid 63 used in suspension plasma spraying contains the solvent 62 containing fluorine, a plurality of yttrium fluoride particles, and a plurality of yttrium oxyfluoride particles.

### TECHNICAL FIELD

The present invention relates to a member for a plasma processing apparatus and a manufacturing method for the same, and for example, relates to a member disposed in a processing chamber of a plasma processing apparatus and exposed to plasma and a manufacturing method for the same.

### BACKGROUND ART

In the manufacture of semiconductor devices such as electronic devices and magnetic memories, plasma etching is used for fine processing. An inner wall of a processing chamber of a plasma processing apparatus that performs plasma etching is exposed to high-frequency plasma and an etching gas during an etching process. Therefore, an inner wall surface of the processing chamber is protected by forming film excellent in plasma resistance. As a technique in the related art relating to a material of such a film having plasma resistance, the following techniques are known.

JP2004-197181A (PTL 1) discloses a film containing a group IIIA element and a fluorine element as a film that covers a surface of an earth portion disposed inside a plasma etching apparatus. The film includes a group IIIA fluoride phase, and the fluoride phase is an orthorhombic system and includes 50% or more of a crystal phase belonging to a space group Pnma.

JP2009-176787A (PTL 2) discloses that a film on a surface of an earth portion disposed inside a plasma etching apparatus is made of a material containing any one or two or more types of Al₂O₃, YAG, Y₂O₃, Gd₂O₃, Yb₂O₃, and YF₃. JP2016-539250A (PTL 3) discloses that a material of a film on a surface of an earth portion disposed inside a plasma etching apparatus includes any one of Y₃Al₅O₁₂, Y₄Al₂O₉, Er₂O₃, Gd₂O₃, Y₂O₃, Er₃Al₅O₁₂, Gd₃Al₅O₁₂, YF₃, and Nd₂O₃, or Y₄Al₂O₉ and a Y₂O₃—ZrO₂ solid solution.

JP2013-140950A (PTL 4) discloses that a material of a film on a surface of an earth portion of a plasma etching apparatus contains yttrium fluoride and yttrium oxyfluoride.

JP2014-141390A (PTL 5), JP2016-27624A (PTL 6), and JP2018-82154A (PTL 7) disclose that a film is formed by an aerosol deposition method using yttrium oxide, yttrium fluoride, and yttrium oxyfluoride each having an average crystallite size of less than 100 nm as a film material of an earth portion disposed inside a plasma etching apparatus. The aerosol deposition method is also known to have features that unevenness on the surface of the formed film can be reduced compared to an atmospheric plasma spraying method.

Meanwhile, Kazuhiro Ueda et al. discloses that when the average crystallite size increases, an amount of generated particles increases in “Advances in X-ray Analysis 50 (Apr. 1, 2019), p. 197 to 205 (Non-PTL 1)” (edited by) The Japan Society for Analytical Chemistry, X-ray Analysis Research Council.

JP2019-192701A (PTL 8) discloses that by setting a crystallite size of a film of an earth portion disposed inside a plasma processing apparatus to 50 nm or less, occurrence of particles on a semiconductor wafer processed inside is reduced. Further, it is also disclosed that by setting a temperature of a parent material of the earth portion when forming the film within a predetermined range, a low-temperature phase ratio can be increased to 60% or more, and the crystallite size can be reduced to 50 nm or less.

JP2017-190475A (PTL 9) discloses a specific range of a mixing ratio of an yttrium fluoride granulated powder and an yttrium oxide granulated powder as a thermal spraying material capable of obtaining a thermally-sprayed coating film of an yttrium-based fluoride compound. The thermal spraying coating film of the yttrium-based fluoride compound has sufficient corrosion resistance against plasma, and can effectively prevent damage to a parent material caused by acid penetration even during washing with an acid.

JP2017-150085A (PTL 10) discloses a step of producing a spraying coating film made of yttrium fluoride capable of preventing generation of a particle. In this step, a high-speed flame spraying method or an atmospheric plasma spraying method is used to supply a slurry containing yttrium fluoride particles having an a average particle diameter in a specific range to a position downstream of a nozzle of a spraying gun or a tip position of the nozzle.

JP2020-172702A (PTL 11) discloses a formation method of a spraying film formed on a component, a member, or the like in a plasma etching apparatus. It is disclosed that the sprayed film is formed by a suspension plasma spraying method by spraying a slurry in which rear earth⋅aluminum⋅mono-clinic (R₄Al₂O₉) is dispersed in a solvent. The suspension plasma spraying is also called SPS or suspension liquid plasma spraying.

CITATION LIST

### Patent Literature

PTL 1: JP2004-197181A
PTL 2: JP2009-176787A
PTL 3: JP2016-539250A
PTL 4: JP2013-140950A
PTL 5: JP2014-141390A
PTL 6: JP2016-27624A
PTL 7: JP2018-82154A
PTL 8: JP2019-192701A
PTL 9: JP2017-190475A
PTL 10: JP2017-150085A
PTL 11: JP2020-172702A

### Non Patent Literature

[Non-PTL 1] Kazuhiro Ueda, Kazuyuki Ikenaga, Tomoyuki Tamura, and Masahiro Kadoya, “Study on the crystal structure and particles generation mechanism of yttrium-based materials for plasma etching apparatus”, (edited by) The Japan Society for Analytical Chemistry, X-ray Analysis Research Council, Advances in X-ray Analysis 50, AGNE Gijutsu Center, issued date: Apr. 1, 2019, p. 197 to 205

### SUMMARY OF INVENTION

### Technical Problem

However, the inventors have found that the techniques in the related art using atmospheric plasma spraying have a problem because the following points are not sufficiently considered.

That is, to reduce a crystal size of the formed film, even when a raw material used for forming the film is finely powdered, the raw material powder is charged and aggregated due to friction between a carrier gas such as dry nitrogen and the raw material powder, and thus an effect of finely powdering the raw material is not sufficiently obtained. In addition, even when the carrier gas containing moisture is used to reduce the charge of the raw material powder, the raw material powder is aggregated due to an adsorption force of water on a surface of the raw material powder, and thus the effect of finely powdering the raw material is not sufficiently obtained. Further, due to the effect of agglomeration of the raw material powder, a part of the raw material powder is deposited in a semi-molten state without being completely melted, which makes it difficult to form a thick microcrystalline layer. That is, in the techniques in the related art using atmospheric plasma spraying, the aggregation of the raw material is not sufficiently considered.

To prevent the aggregation of raw material powder, a suspension plasma spraying method using a suspension liquid in which the raw material is dispersed in a solvent is effective.

In the suspension plasma spraying in PTL 11, a method suspending an oxide raw material in a solvent is disclosed. In the suspension plasma spraying method using a suspension liquid in which a raw material is dispersed in water or an organic solvent such as ethanol, the solvent in the suspension liquid functions as a thermally activated solution that reacts with the raw material powder, and thus more energy is generated than that in the atmospheric plasma spraying method. Therefore, in the suspension plasma spraying, since the raw material powder is completely melted and deposited, a thick microcrystalline layer can be formed as compared with the atmospheric plasma spraying method.

However, the inventors have found that in the suspension plasma spraying method using a suspension liquid in which a raw material is dispersed in a solvent, when a fluoride or an oxyfluoride is used as the raw material, the following problems will be generated.

That is, in the formation step of the film by the suspension plasma spraying method, the raw material powder containing the fluoride or the oxyfluoride is thermally decomposed and reacts with oxygen generated from the solvent or oxygen in the atmosphere, thereby generating an oxide. As a result, an yttrium oxide is mixed into the formed film. When such a film is used in the plasma etching apparatus, the film is exposed to fluorine plasma used in etching processing, and an yttrium oxide portion in the film reacts with the fluorine plasma and changes into a fluoride. At this time, a volume of the yttrium oxide portion expands, and thus cracks are generated on the surface of the film. As a result, minute particles scatter from the film. When the scattering minute particles adhere to a processing target object such as a semiconductor wafer as particles, plasma processing on the processing target object is not performed normally. As a result, the yield of the plasma processing on the processing target object decreases. In the techniques in the related art, a condition under which a spraying coating film capable of sufficiently preventing the generation of the minute particles is formed is not sufficiently considered.

The main object of the present application is to reduce generation of particles from a member for a plasma processing apparatus. Other problems and novel features will be clarified according to the description of the present specification and the accompanying drawings.

### Solution to Problem

An outline of a representative one among embodiments disclosed in the present application will be briefly described as follows.

In a method for manufacturing a member for a plasma processing apparatus according to one embodiment, a coating film is formed on a base material of a member for a plasma processing apparatus using a suspension plasma spraying method. A suspension liquid used in suspension plasma spraying contains a solvent containing fluorine, a plurality of yttrium fluoride particles, and a plurality of yttrium oxyfluoride particles.

### Advantageous Effects of Invention

According to one embodiment, generation of particles from a coating film on a surface of a member disposed in a processing chamber of a plasma processing apparatus can be reduced, and the life of the coating film can be extended.

### BRIEF DESCRIPTION OF DRAWINGS

FIG. 1 is a longitudinal cross sectional view illustrating a schematic configuration of a plasma processing apparatus according to one embodiment.

FIG. 2 is a view illustrating a formation method of a coating film in one embodiment.

FIG. 3 is an SEM image of a cross section of the coating film.

FIG. 4 is an SEM image of the cross section of the coating film.

FIG. 5 is an SEM image of the cross section of the coating film.

### DESCRIPTION OF EMBODIMENTS

Hereinafter, embodiments will be described in detail with reference to the drawings. In all the drawings for describing the embodiments, members having the same function are denoted by the same reference numeral, and the repeated description thereof is omitted. In the following embodiments, a description of the same or similar parts will not be repeated in principle unless particularly necessary.

### Embodiment 1

### Configuration of Plasma Processing Apparatus

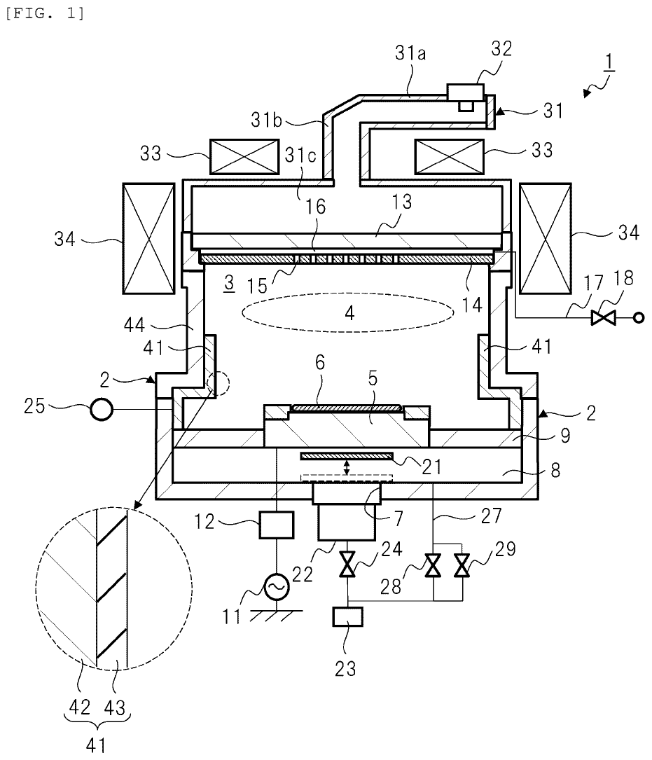

Hereinafter, a plasma processing apparatus 1 according to the present embodiment will be described with reference to FIG. 1. FIG. 1 is a longitudinal cross sectional view illustrating schematic configuration of the plasma processing apparatus 1 according to the present embodiment.

As illustrated in FIG. 1, the plasma processing apparatus 1 includes a vacuum container 2. A processing chamber 3 is a space inside the vacuum container 2. The processing chamber 3 is surrounded by an inner wall of the vacuum container 2. An upper portion of the processing chamber 3 is a space surrounded by an inner wall having a cylindrical shape, and forms a discharge chamber (plasma generation chamber) in which plasma 4 is formed.

A stage 5 serving as a sample table is disposed in the processing chamber 3 below the discharge chamber in which the plasma 4 is formed. A wafer 6 serving as a processing target object is disposed and held on an upper surface of the stage 5. The stage 5 is a member having a cylindrical shape. A central axis of the stage 5 and a central axis of the discharge chamber are disposed coaxially or at positions approximate to an extent allowing the central axes to be regarded as being coaxial.

A bottom portion of the vacuum container 2 is formed with an exhaust port 7. An upper surface of the bottom portion of the vacuum container 2 forms a bottom surface of the processing chamber 3. The exhaust port 7 is disposed below the stage 5. A central axis of the exhaust port 7 in an up-down direction and a central axis of the stage 5 in the up-down direction are disposed coaxially or at positions approximate to an extent allowing the central axes to be regarded as being coaxial.

A space 8 is disposed between the bottom surface of the processing chamber 3 in which the exhaust port 7 is formed and a lower surface of the stage 5. The space 8 forms a lower portion of the processing chamber 3. The stage 5 is held at an intermediate position between an upper end surface and a lower end surface of the processing chamber 3 in the up-down direction of the processing chamber 3. In the processing chamber 3, a ring-shaped exhaust plate 9 is disposed to surround the stage 5. A plurality of through holes (not illustrated) are formed in the exhaust plate 9. The plurality of through holes communicate a space above the exhaust plate 9 in the processing chamber 3 with the space 8 below the exhaust plate 9. The space 8 below the stage 5 communicates with the discharge chamber through the plurality of through holes in the exhaust plate 9 and gaps between a side wall of the stage 5 and the inner wall having a cylindrical shape of the processing chamber 3. Products generated on an upper surface of the wafer 6 and in the discharge chamber during processing on the wafer 6 on the stage 5 and the plasma and gas particles in the discharge chamber are discharged out of the processing chamber 3 through the exhaust port 7 via the space 8. Therefore, the space 8 forms an exhaust path.

Although a detailed configuration of the stage 5 is not illustrated, the stage 5 includes a base material which is a member formed of a metal and having a cylindrical shape, a dielectric film disposed to cover an upper surface of the base material, a heater disposed inside the dielectric film, and a coolant flow path disposed inside the base material. In the stage 5, around the central axis of the stage 5, the coolant flow path is disposed concentrically, or the coolant flow paths are disposed spirally in a multiple manner. Further, in a state in which the wafer 6 is disposed on an upper surface of the dielectric film of the stage 5, a gas having a heat transfer property such as a helium (He) gas is supplied to a gap between a lower surface of the wafer 6 and the upper surface of the dielectric film. Therefore, a pipe through which the gas having a heat transfer property flows is disposed inside the base material and the dielectric film in the stage 5.

A high-frequency power supply 11 is connected to the base material of the stage 5 via an impedance matching machine 12 and a coaxial cable. The high-frequency power supply 11 supplies high-frequency power to the base material of the stage 5 during the processing on the wafer 6 by the plasma 4. The high-frequency power forms an electric field for attracting charged particles in the plasma 4 above the upper surface of the wafer 6.

In the stage 5, an electrode for electrostatic adsorption is disposed above the heater in the dielectric film on the base material. When DC power is supplied to the electrode, an electrostatic force for adsorbing and holding the wafer 6 onto the upper surface of the dielectric film is generated inside the dielectric film and the wafer 6.

A window member 13 is disposed above the upper surface of the stage 5 to face the stage 5. The window member 13 is made of a dielectric such as quartz or ceramics, and has a circular plate shape. The window member 13 forms an upper portion of the vacuum container 2 and hermetically seals the processing chamber 3. A shower plate 14 is disposed below the window member 13 at a position forming a ceiling surface of the processing chamber 3. The shower plate 14 is made of a dielectric such as quartz, and has a circular plate shape. A plurality of through holes 15 are formed in a central portion of the shower plate 14. The shower plate 14 is disposed such that a gap (space) 16 is formed between a lower surface of the window member 13 and the shower plate 14. The window member 13 or the shower plate 14 forms a ceiling of the processing chamber 3.

A processing gas supply pipe 17 is connected to the vacuum container 2 to communicate with the gap 16. A valve 18 for opening or closing an interior of the processing gas supply pipe 17 is disposed at a predetermined position on the processing gas supply pipe 17. A gas for processing (processing gas) to be supplied into the processing chamber 3 flows into the gap 16 through the processing gas supply pipe 17 in which the valve 18 is opened, is diffused in the gap 16, and is supplied into the processing chamber W through the plurality of through holes 15 in the shower plate 14. Therefore, the processing gas is supplied into the processing chamber 3 from above. A flow rate or a speed of the processing gas is adjusted by a gas flow rate control unit (not illustrated) connected to one end side of the processing gas supply pipe 17.

A vacuum exhaust unit for exhausting gases and particles in the processing chamber 3 through the exhaust port 7 is disposed below the vacuum container 2. The vacuum exhaust unit includes a pressure adjustment plate 21 and a turbo molecular pump 22 which is a vacuum pump. The pressure adjustment plate 21 is a circular plate-shaped valve. The pressure adjustment plate 21 moves up and down above the exhaust port 7 to increase and decrease an area of a flow path through which the gas flows into the exhaust port 7. In the vacuum exhaust unit, an outlet of the turbo molecular pump 22 is connected, via an exhaust pipe, to a dry pump 23 which is a roughing pump. A valve 24 is disposed on the exhaust pipe.

The pressure adjustment plate 21 also has a function as a valve for opening and closing the exhaust port 7. The vacuum container 2 is provided with a pressure detector 25 which is a sensor for detecting pressure in the processing chamber 3. A signal output from the pressure detector 25 is transmitted to a control unit (not illustrated), and a pressure value is detected. According to the detected pressure value, the pressure adjustment plate 21 is driven based on a command signal output from the control unit. Accordingly, a position of the pressure adjustment plate 21 in the up-down direction is changed to increase and decrease the area of the flow path through which the gas flows into the exhaust port 7.

The dry pump 23 is connected to the vacuum container 2 via an exhaust pipe 27. A valve 28 and a valve 29 are connected to the exhaust pipe 27. The valve 28 is a slow exhaust value for slowly exhausting the processing chamber 3 from atmospheric pressure to vacuum by the dry pump 23. The valve 29 is a main exhaust valve for exhausting the processing chamber 3 at a high speed by the dry pump 23.

A plasma formation unit is disposed above a cylindrical portion of an upper portion of the vacuum container 2 and on the periphery surrounding a side wall of the cylindrical portion. The plasma formation unit has a configuration of generating an electric field or a magnetic field supplied to the processing chamber 3 to generate the plasma 4. The plasma formation unit includes a waveguide tube 31, a magnetron oscillator 32, a solenoid coil 33, and a solenoid coil 34.

That is, the waveguide tube 31 is disposed above the window member 13. The magnetron oscillator 32 that oscillates and outputs an electric field of a microwave is disposed at one end portion of the waveguide tube 31. The waveguide tube 31 is a pipeline through which the electric field of the microwave output from the magnetron oscillator 32 propagates. The electric field of the microwave propagating in the waveguide tube 31 is supplied into the processing chamber 3. The waveguide tube 31 includes a rectangular waveguide tube portion 31a extending in a horizontal direction and a circular waveguide tube portion 31b extending in the up-down direction. A longitudinal cross section of the rectangular waveguide tube portion 31a has a rectangular shape. The magnetron oscillator 32 is disposed at one end portion of the rectangular waveguide tube portion 31a. The circular waveguide tube portion 31b is connected to the other end portion of the rectangular waveguide tube portion 31a. A cross section of the circular waveguide tube portion 31b has a circular shape, and a central axis thereof extends in the up-down direction. A hollow portion 31c having a cylindrical shape enlarged in a radial direction is disposed at a lower end portion of the circular waveguide tube portion 31b. An electric field of a specific mode is strengthened inside the hollow portion 31c. A plurality of stages of the solenoid coils 33 and the solenoid coil 34, which are magnetic field generation units, are disposed above and around the hollow portion 31c and around a lateral side of the processing chamber 3.

### Operation of Plasma Processing Apparatus

Next, an operation of the plasma processing apparatus 1 will be described.

The wafer 6 serving as a processing target object is transferred within a transfer chamber inside a vacuum transfer container (not illustrated) connected to a side wall of the vacuum container 2, and is transferred into the processing chamber 3 of the vacuum container 2 of the plasma processing apparatus 1. Specifically, the wafer 6 is placed on a tip portion of an arm of a vacuum transfer device (not illustrated) such as a robot arm disposed in the transfer chamber, transferred into the processing chamber 3 of the vacuum container 2, and placed on the upper surface of the stage 5.

When the arm of the vacuum transfer device leaves the processing chamber 3, an interior of the processing chamber 3 is sealed, and a DC voltage is applied to an electrode for electrostatic adsorption in the dielectric film of the stage 5. The wafer 6 is held on the dielectric film of the stage 5 by an electrostatic force generated in this way. In this state, the gas having a heat transfer property such as He is supplied to a gap between the wafer 6 and the upper surface of the dielectric film of the stage 5 through the pipe inside the stage 5. A coolant whose temperature is adjusted by a coolant temperature adjuster is supplied to the coolant flow path inside the stage 5. Accordingly, heat transfer between the base material of the stage 5 whose temperature is adjusted and the wafer 6 is promoted, and a temperature of the wafer 6 is adjusted to within a temperature range appropriate for the plasma processing.

The processing gas whose flow rate or speed is adjusted by the gas flow rate control unit passes through the processing gas supply pipe 17, and is supplied from the gap 16 into the processing chamber 3 through the plurality of through holes 15 in the shower plate 14. Further, an interior of the processing chamber 3 is exhausted from the exhaust port 7 by an operation of the turbo molecular pump 22. Due to a balance between the supply of the processing gas into the processing chamber 3 and the exhaust from the exhaust port 7, the pressure in the processing chamber 3 is adjusted to within a pressure range suitable for the plasma processing. In this state, the electric field of the microwave oscillated from the magnetron oscillator 32 propagates in the waveguide tube 31, passes through the window member 13 and the shower plate 14, and is radiated into the processing chamber 3. Further, a magnetic field generated by the solenoid coils 33 and 34 is supplied to the processing chamber 3, and electron cyclotron resonance (ECR) is generated by interaction between the magnetic field and the electric field of the microwave. Accordingly, atoms or molecules of the processing gas are excited, ionized, and dissociated, thereby generating the plasma 4 in the processing chamber 3.

When the plasma 4 is generated, the high-frequency power is supplied from the high-frequency power supply 11 to the base material of the stage 5, and a bias potential is formed above the upper surface of the wafer 6. Accordingly, the charged particles such as ions in the plasma 4 are attracted to the upper surface of the wafer 6. A structure including a processing target film and a mask layer on the film is formed in advance on the upper surface of the wafer 6. Therefore, the processing target film on the upper surface of the wafer 6 is etched. Since the processing target film exposed from the mask layer is selectively etched, the etching of the processing target film proceeds along a shape of the mask layer. When a detector (not illustrated) detects that etching processing on the processing target film reaches an end point, the supply of the high-frequency power from the high-frequency power supply 11 to the stage 5 is stopped, and the plasma 4 is turned off. Accordingly, the etching processing is stopped.

When the control unit determines that there is no need to further cause the etching processing on the wafer 6 to progress, high vacuum exhaust in the processing chamber 3 is performed. Then, static electricity of the stage 5 is removed, and the adsorption of the wafer 6 is released. Thereafter, the arm of the vacuum transfer device enters the processing chamber 3, and the processed wafer 6 is delivered onto the arm, and then, as the arm contracts, the wafer 6 is transferred to the vacuum transfer chamber outside the processing chamber 3.

### Earth Electrode

The inner wall (inner side wall surface) of the processing chamber 3 of the plasma processing apparatus 1 faces the plasma 4 and is a surface exposed to particles in the plasma 4. Meanwhile, to stabilize a potential of the plasma 4 which is a dielectric, it is necessary to dispose a member facing the plasma 4 and functioning as an electrode for earth in contact with the plasma 4 in the processing chamber 3.

In the plasma processing apparatus 1 of the present embodiment, an earth electrode 41 is disposed in the processing chamber 3. The earth electrode 41 has a function as an electrode for earth. The earth electrode 41 is a ring-shaped member. The earth electrode 41 covers a part of a surface of the inner wall of the processing chamber 3 surrounding the discharge chamber. The earth electrode 41 is disposed to surround the periphery (lateral periphery) of the space above the upper surface of the stage 5. In the up-down direction, at least a part of the earth electrode 41 is located at a position higher than the upper surface of the stage 5.

The earth electrode 41 includes a base material (parent material) 42 made of a material having conductivity and a coating film 43 that covers a surface of the base material 42. In the present embodiment, the base material 42 of the earth electrode 41 is made of a metal such as a stainless alloy or an aluminum alloy. The earth electrode 41 is grounded.

When the plasma processing apparatus 1 is in operation, the plasma 4 is formed in the processing chamber 3, and the earth electrode 41 is exposed to the plasma 4. Since the earth electrode 41 includes the coating film 43, the coating film 43 of the earth electrode 41 is exposed to the plasma 4.

Unlike the present embodiment, when the earth electrode 41 does not include a coating film on the surface of the base material 42, the base material 42 of the earth electrode 41 is exposed to the plasma 4, which may cause corrosion of the base material 42 of the earth electrode 41 or generation of particles from the base material 42. As a result, contamination of the wafer 6 is concerned.

Therefore, in the present embodiment, the coating film 43 made of a material having high plasma resistance is formed to cover the surface of the base material 42 of the earth electrode 41. Since the coating film 43 covering the base material 42 is formed, damage to the base material 42 of the earth electrode 41 caused by the plasma 4 can be prevented while maintaining the function as an electrode of the earth electrode 41. As a result, it is possible to prevent the corrosion of the earth electrode 41, prevent the earth electrode 41 from becoming a generation source of particles, and prevent the wafer 6 from being contaminated. The coating film 43 may be a stacked film.

In the present embodiment, the coating film 43 of the earth electrode 41 contains yttrium fluoride and yttrium oxyfluoride. Yttrium fluoride and yttrium oxyfluoride are excellent as a coating film material having high plasma resistance. Therefore, the coating film 43 containing yttrium fluoride and yttrium oxyfluoride has high resistance to the plasma.

In the present embodiment, the coating film 43 of the earth electrode 41 is formed using the suspension plasma spraying method. As compared with the atmospheric plasma spraying method, the suspension plasma spraying method has an advantage that aggregation of raw material particles used for spraying hardly occurs. In the present embodiment, since the coating film 43 containing yttrium fluoride and yttrium oxyfluoride is formed by the suspension plasma spraying method, the suspension liquid used when the coating film 43 is formed contains yttrium fluoride particles and yttrium oxyfluoride particles.

However, according to the study of the inventors, it has been found that when a coating film is formed by the suspension plasma spraying method using a suspension liquid containing yttrium fluoride particles and yttrium oxyfluoride particles, yttrium oxide is likely to be mixed into the formed coating film. When a ratio of yttrium oxide in the coating film containing yttrium fluoride, yttrium oxyfluoride, and yttrium oxide increases, particles are likely to be generated from the coating film when the coating film is exposed to the plasma in the processing chamber of the plasma processing apparatus. Therefore, it is desirable to reduce the ratio of yttrium oxide in the coating film.

Therefore, in the present embodiment, a solvent containing fluorine is used as a solvent of the suspension liquid used when the coating film 43 is formed. That is, when the coating film 43 is formed by the suspension plasma spraying method, a suspension liquid containing the solvent containing fluorine, yttrium fluoride particles, and yttrium oxyfluoride particles is used. Accordingly, it is possible to prevent yttrium oxide from being mixed into the coating film 43 and to reduce a content of yttrium oxide in the coating film 43. This will be described in more detail later.

Meanwhile, a member made of a metal such as a stainless alloy or an aluminum alloy is used in a base material 44 of the vacuum container 2 which does not have a function as the earth. A surface of the base material 44 of the vacuum container 2 is also subjected to spraying, PVD, CVD, and other processing or passivation to improve corrosion resistance to the plasma and reduce consumption. Accordingly, it is possible to prevent the generation of corrosion, metal contamination, or generation of particles caused by the exposure of the base material 44 of the vacuum container 2 to the plasma 4.

A cylindrical cover member (not illustrated) made of ceramics such as yttrium oxide or quartz may be disposed inside the inner wall surface of the base material 44 having a cylindrical shape and between the discharge chamber and the base material 44. By disposing such a cover member between the base material 44 and the plasma 4, contact between highly reactive particles in the plasma 4 and the base material 44 and a collision between the base material 44 and the charged particles are blocked or reduced, and the consumption of the base material 44 can be reduced.

### Formation Method of Coating Film

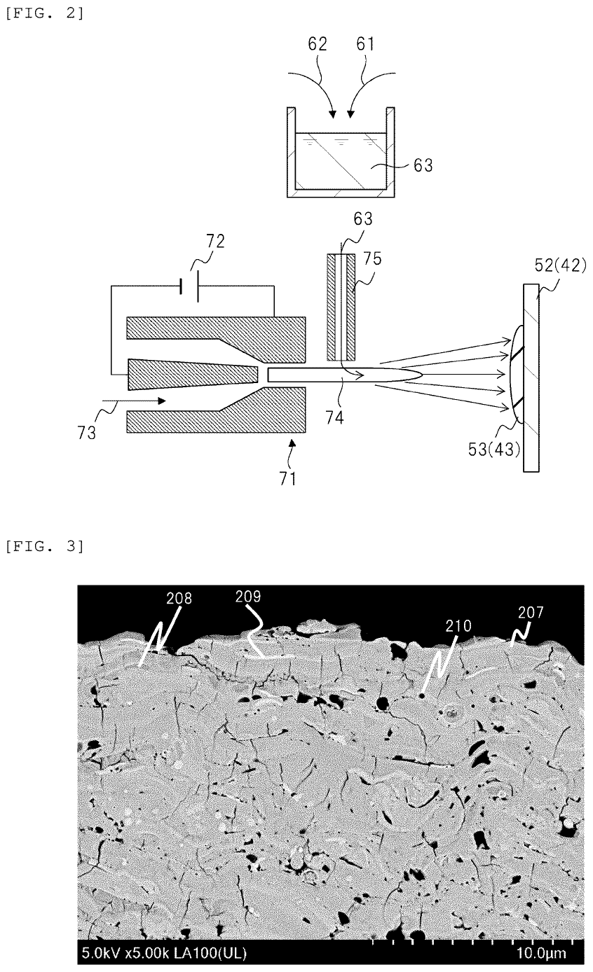

A formation method of the coating film according to the present embodiment will be described below with reference to FIG. 2. FIG. 2 is a view illustrating the formation method of the coating film in the present embodiment.

The earth electrode 41 in a state in which there is no coating film 43 formed thereon is prepared. At this stage, the coating film 43 is not formed on the surface of the base material 42 of the earth electrode 41, and the surface of the base material 42 of the earth electrode 41 is exposed.

Next, to improve adhesion between the surface of the base material 42 of the earth electrode 41 and the coating film 43 to be formed thereon, the surface of the base material 42 is subjected to roughening processing using a sandblasting method. A surface roughness Ra of the base material 42 is preferably 1 μm or more (Ra≥1 μm).

Next, the surface of the base material 42 of the earth electrode 41 contaminated by the sandblasting method is subjected to degrease cleansing processing. The degrease cleansing processing can be performed by ultrasonic cleaning using an organic solvent such as acetone. The degrease-cleansed surface of the base material 42 of the earth electrode 41 becomes a surface of a base material 52 illustrated in FIG. 2. That is, the base material 52 illustrated in FIG. 2 corresponds to the base material 42 of the earth electrode 41.

Next, a step of forming a coating film 53 on the surface of the base material 52 using the suspension plasma spraying method is performed. This step will be described below. The coating film 53 corresponds to the coating film 43 of the earth electrode 41 described above.

A thermal spraying material (material for thermal spraying) 61 and a solvent (dispersion solvent) 62 are placed in a stirrer (not illustrated) and stirred to produce (prepare) a suspension liquid (liquid suspension liquid) 63 in which thermal spraying material 61 is dispersed in the solvent 62.

The thermal spraying material 61 used in the present embodiment contains a plurality of yttrium fluoride particles and a plurality of yttrium oxyfluoride particles. Here, the thermal spraying material 61 including the plurality of yttrium fluoride particles and the plurality of yttrium oxyfluoride particles is used. It is desirable for the thermal spraying material 61 to not contain yttrium oxide particles. The solvent 62 is a solvent (dispersion solvent) in which the thermal spraying material 61 is dispersed. Particles forming the thermal spraying material 61 are dispersed in the solvent 62. The solvent 62 used in the present embodiment contains fluorine. Here, a fluorocarbon liquid made of chlorofluorocarbon (CFC) is used as the solvent 62.

Therefore, the suspension liquid 63 used in the present embodiment is a suspension liquid containing a solvent containing fluorine, the plurality of yttrium fluoride particles, and the plurality of yttrium oxyfluoride particles.

It is preferable that the yttrium fluoride particles and the yttrium oxyfluoride particles which form the thermal spraying material 61 both have an average crystallite size of 50 nm or less. It is preferable that the yttrium fluoride particles and the the yttrium oxyfluoride particles which form the thermal spraying material 61 both have an average particle diameter of 0.05 μm or more. When the average particle diameter is less than 0.05 μm, the particles are charged due to the friction between the solvent and the particles, and the particles are aggregated in the suspension liquid 63. It is preferable that the yttrium fluoride particles and the yttrium oxyfluoride particles which form the thermal spraying material 61 both have an average particle diameter of 50 μm or less. When the average particle diameter is more μm, the particles precipitate in the solvent, and the suspension liquid 63 does not sufficiently function as an appropriate suspension liquid. A total content of the yttrium fluoride particles and the yttrium oxyfluoride particles in the suspension liquid 63 is preferably 10% by weight or more and 70% by weight or less.

A high voltage 72 is applied to a nozzle 71 of a thermal spraying device, and a plasma gas 73 is caused to flow through the nozzle 71 to generate arc discharge, thereby generating a thermal spraying flame (plasma jet) 74. The plasma gas 73 is a gas for plasma generation, and for example, an argon gas alone or a nitrogen gas alone, or a mixed gas of two or more types selected from an argon gas, a hydrogen gas, a helium gas, and a nitrogen gas is used, but is not particularly limited thereto. The thermal spraying flame 74 is a plasmarized gas jet ejected from the nozzle 71.

The suspension liquid 63 produced as described above is introduced into a suspension liquid supply pipe 75, is caused to pass through the suspension liquid supply pipe 75, and is put into the thermal spraying flame 74. The suspension liquid 63 put into the thermal spraying flame 74 is heated by the thermal spraying flame 74. Accordingly, the solvent 62 contained in the suspension liquid 63 is volatilized, and the yttrium fluoride particles and the yttrium oxyfluoride particles which are the thermal spraying material 61 contained in the suspension liquid 63 are in a molten state. At this time, a part of yttrium fluoride and a part of yttrium oxyfluoride are thermally decomposed into yttrium ions, fluorine ions, and oxygen ions. Then, when the thermally decomposed yttrium fluoride and yttrium oxyfluoride are recombined, yttrium fluoride, yttrium oxyfluoride, and yttrium oxide are formed, and are thermally sprayed onto the base material 52.

In the suspension plasma spraying method in the related art, an organic solvent such as water (H₂O) or ethanol (C₂H₅OH) is used as a solvent for producing a suspension liquid. In this case, yttrium oxide is likely to be formed when yttrium fluoride and yttrium oxyfluoride thermally decomposed in the thermal spraying flame are recombined. This is because oxygen in the atmosphere and oxygen generated by the decomposition of the solvent (water or organic solvent) exist, and therefore the environment at the time of recombination is an environment in which a large amount of oxygen exists.

In contrast, in the suspension plasma spraying method in the present embodiment, a solvent containing fluorine is used as the solvent 62 contained in the suspension liquid 63, and here, a fluorocarbon liquid made of CFC is used. Therefore, in the thermal spraying flame 74, oxygen in the atmosphere, oxygen generated from yttrium oxyfluoride, fluorine generated from yttrium fluoride, fluorine generated from yttrium oxyfluoride, and fluorine generated from the solvent (fluorocarbon liquid) exist around a material melt (melt of the thermal spraying material 61). Electronegativity of fluorine is larger than electronegativity of oxygen. Therefore, when yttrium fluoride and yttrium oxyfluoride that are thermally decomposed in the thermal spraying flame 74 are recombined, a probability of yttrium oxyfluoride being formed again is higher than a probability of yttrium oxide being formed. As a result, it is possible to reduce the probability of yttrium oxide being formed when yttrium fluoride and yttrium oxyfluoride that are thermally decomposed in the thermal spraying flame 74 are recombined. Therefore, as compared with a case in which water or an organic solvent is used as the solvent 62, yttrium oxide formed in the thermal spraying flame 74 can be reduced when a solvent (here, CFC) containing fluorine is used as the solvent 62 as in the present embodiment.

The melted yttrium fluoride, the melted yttrium oxyfluoride, and the melted yttrium oxide are thermally sprayed onto and adhere to the base material 52, and are cooled and solidified. Accordingly, a mixed film of yttrium fluoride crystals, yttrium oxyfluoride crystals, and yttrium oxide crystals is formed on the base material 52. This operation is repeated to stack the mixed films, thereby forming the coating film 53 having a thickness of, for example, about 100 μm. The coating film 53 is made of a mixture of yttrium fluoride, yttrium oxyfluoride, and yttrium oxide.

Ratios of crystal phases contained in the coating film 53 formed by the suspension plasma spraying method of the present embodiment are 3% by weight for an orthorhombic crystal YF₃ phase, 3% by weight for a hexagonal crystal YF₃ phase, 56% by weight for an orthorhombic crystal Y₅O₄F₇ phase, 36% by weight for a hexagonal crystal Y—O—F phase, and 2% by weight for a monoclinic crystal Y₂O₃ phase. The crystal phase ratios are determined by semi-quantitative analysis using a reference intensity ratio (RIR) method on an X-ray diffraction intensity.

In contrast, when the coating film 53 is formed by the suspension plasma spraying method using water or an organic solvent as the solvent 62, ratios of crystal phases contained in the coating film 53 are 3% by weight for an orthorhombic crystal YF₃ phase, 3% by weight for a hexagonal crystal YF₃ phase, 41% by weight for an orthorhombic crystal Y₅O₄F₇ phase, 41% by weight for a hexagonal crystal Y—O—F phase, 6% by weight for a monoclinic crystal Y₂O₃ phase, and 5% by weight for a cubic crystal Y₂O₃ phase. According to the study of the inventors, in the suspension plasma spraying method using water or an organic solvent as the solvent 62, the yttrium oxide phase in the formed coating film 53 cannot be reduced to 5% by weight or less.

Therefore, it is confirmed that the ratios of the yttrium oxide phases in the coating film 53 can be reduced when the coating film 53 is formed by the suspension plasma spraying method using the fluorocarbon liquid (CFC) as the solvent 62 as in the present embodiment, compared with the case in which the coating film 53 is formed by the suspension plasma spraying method using water or an organic solvent as the solvent 62.

To prevent the particles from generating from the coating film 53 when the coating film 53 is exposed to the plasma 4 in the processing chamber 3 of the plasma processing apparatus 1, the content of yttrium oxide in the coating film 53 is preferably 9% by weight or less, and more preferably 5% by weight or less. Such a content of yttrium oxide can be implemented by the formation method of the coating film 53 of the present embodiment.

In the coating film 53, a case in which the content ratio of yttrium oxide is zero, that is, a case in which the coating film 53 does not contain yttrium oxide is also allowed.

FIG. 3 is an SEM image of a cross section of the coating film 53 when the coating film 53 is formed on the base material 52 by the suspension plasma spraying method using the fluorocarbon liquid (CFC) as the solvent 62 as in the present embodiment.

In the SEM image in FIG. 3, jet-black regions are the vacancies 210. From results of an SEM-EDX analysis, it is confirmed that an oxygen concentration increases as a contrast of the SEM image is brighter (whiter), and a fluorine concentration increases as the contrast is darker (blacker). A bright region (white region) 209 is a region in which the oxygen concentration is high, and is considered to be mainly made of yttrium oxide. A dark region (black region) 208 is a region in which the fluorine concentration is high, and is considered to be mainly made of yttrium fluoride. A region 207 having a brightness (color) intermediate between the region 208 and the region 209 is considered to be mainly made of yttrium oxyfluoride based on determination based on the oxygen concentration and the fluorine concentration. It is confirmed that the crystallite size of the surface of the coating film 53 is 30 nm or less from an XRD analysis of the coating film 53. By observation of the cross section STEM, in the coating film 53 of the present embodiment, it can be determined that a microcrystalline layer is formed in a region from the surface of the coating film 53 to a depth of 10 μm. In addition, when considered together with the XRD analysis results, it is possible to estimate that the thickness of the microcrystalline layer having a crystallite size of 30 nm or less is 10 μm or more.

To prevent the particles from being generated from the coating film 53 when the coating film 53 is exposed to the plasma 4 in the processing chamber 3 of the plasma processing apparatus 1, an average size of the crystallites in the yttrium fluoride phases in the coating film 53 and an average size of the crystallites in the yttrium oxyfluoride phases in the coating film 53 are preferably 50 nm or less. Such average sizes of the crystallites can be implemented by the formation method of the coating film 53 of the present embodiment.

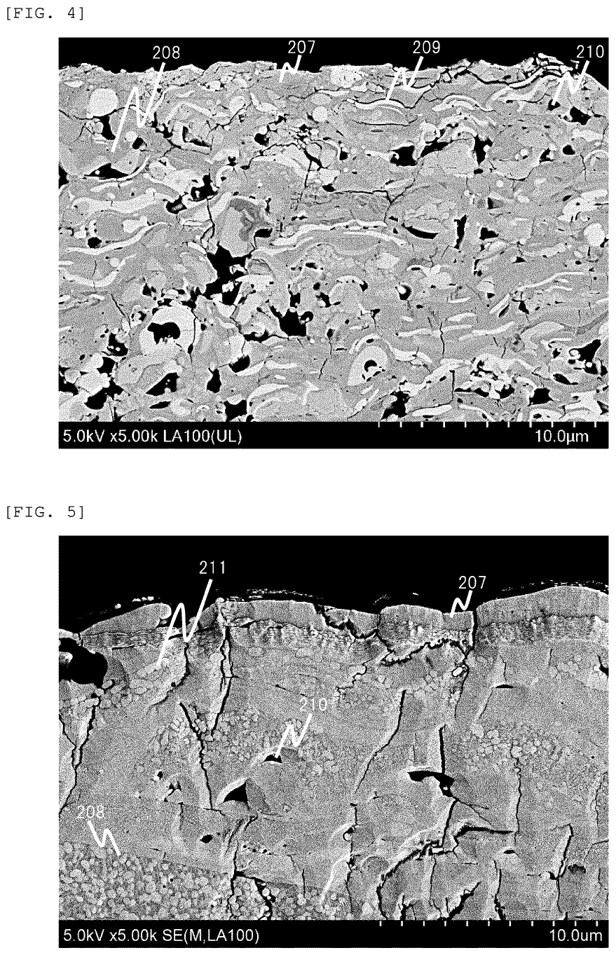

FIG. 4 is an SEM image of a cross section of the coating film 53 when the coating film 53 is formed on the base material 52 by the suspension plasma spraying method using water or an organic solvent as the solvent 62. It is clearly confirmed that in the SEM image in FIG. 4, there are more bright regions (white regions) 209 made of yttrium oxide than those in the SEM image in FIG. 3. Further, as compared with the SEM image in FIG. 3, regions close to white and regions close to black are dispersed over a wide range even within the region 207 having an intermediate color in the SEM image in FIG. 4.

Therefore, it is also confirmed from the SEM images that the ratios of the yttrium oxide phases in the coating film 53 can be reduced when the coating film 53 is formed by the suspension plasma spraying method using the fluorocarbon liquid (CFC) as the solvent 62 as in the present embodiment, compared with the case in which the coating film 53 is formed by the suspension plasma spraying method using water or an organic solvent as the solvent 62.

FIG. 5 is an SEM image of a cross section of the coating film 53 when the coating film 53 is formed on the base material 52 by the atmospheric plasma spraying method without using the suspension liquid.

As compared with FIGS. 3 and 4, in the SEM image in FIG. 5, a region in which the oxygen concentration is high (white region) is hardly formed in the coating film 53. This suggests that yttrium oxide is hardly generated. However, in the SEM image in FIG. 5, remaining particle portions 211 are also observed in the vicinity of the surface of the coating film 53. Here, the remaining particle portion 211 is formed by stacking the raw material particles in a semi-molten state.

When the coating film 53 is formed by the atmospheric plasma spraying method, it is difficult to reduce the crystallite size in the vicinity of the surface of the coating film 53 to 30 nm or less due to an influence of the aggregation of the raw material particles. In the atmospheric plasma spraying method, it is known that the raw material particles in the semi-molten state are deposited during the film formation. Since the remaining particle portion 211 is heated at the time of thermal spraying, the remaining particle portion 211 contains coarse crystals in which crystals grow inside the particles. Since a speed of the solid is larger than that of the liquid due to the air resistance in the atmosphere, the semi-molten particles reach the base material 52 earlier than the molten raw material. As a result, the remaining particle portion 211 is first deposited on the base material 52, and the molten raw material is deposited thereon to be finely crystallized. Therefore, the coating film 53 formed by the atmospheric plasma spraying method has a stacked structure in which the microcrystalline layer is present on the surface thereof and the remaining particle portion 211 is present therein.

When the plasma etching apparatus is operated, the coating film 53 disposed inside the processing chamber gradually decreases in thickness due to the influence of reaction with the plasma gas or ion collision. When the microcrystalline layer on the surface of the coating film 53 disappears and the remaining particle portion 211 containing large crystallites is exposed on the surface of the coating film 53, the particles are generated due to the remaining particle portion 211. This point in time is determined to be the end of the life of the coating film 53. Therefore, reducing the number of remaining particle portions 211 in the coating film 53 and thickening the microcrystalline layer on the surface of the coating film 53 lead to extending the life of the coating film 53.

In the present embodiment, since the coating film 53 is formed by the suspension plasma spraying method instead of the atmospheric plasma spraying method, it is possible to suppress or prevent the remaining particle portions 211 from being generated in the coating film 53. Further, the microcrystalline layer on the surface of the coating film 53 can be thickened. As a result, the life of the coating film 53 can be extended.

A small amount of yttrium oxide is present in the vicinity of the surface of the coating film 53 in FIG. 3. It is also conceivable that the small amount of yttrium oxide affects the generation of particles, but considering the probability, there is almost no effect. Reasons thereof are as follows.

When the plasma etching apparatus is in operation, an event in which the particles having a generation source as the inner wall of the processing chamber fall on the wafer occurs when a crack is generated in a crystal having a size larger than a size of a crystal detected as the particles among a large number of crystals on the inner wall surface, causing fragments to scatter, and these scattering fragments accidentally fall on the wafer. An occurrence probability of the event is 10⁻¹² to 10⁻¹³ level when being approximately estimated based on an area of the inner wall, the crystallite size of an inner wall material, the number of crystals, a wafer diameter, and an inner diameter of the processing chamber. That is, to detect the generation of the particles from the surface of the coating film 53, Y₂O₃ crystals need to be collectively exposed on the surface of the coating film 53. Therefore, it is considered that yttrium oxide observed in the SEM image in FIG. 3 hardly affects the generation of the particles.

As described above, according to the present embodiment, it is possible to form the coating film 53 having low contents of the yttrium oxide phases. Further, the coating film 53 having a thick surface microcrystalline layer whose average crystallite size is 30 nm or less on the surface can be formed. In the processing chamber 3 of the plasma processing apparatus 1 in which a member (here, the earth electrode 41) including the coating film 53 is disposed, the generation of the particles from the coating film 53 is reduced, and the life of the coating film 53 can be extended.

In the present embodiment, chlorofluorocarbon (CFC) is used as the solvent 62. As the solvent 62, any one of fluorocarbon (FC), hydrochlorofluorocarbon (HCFC), and hydrofluorocarbon (HFC) may be used. Alternatively, a mixed liquid of two or more of CFC, FC, HCFC, and HFC can be used as the solvent 62. Therefore, a fluorocarbon liquid can be used as the solvent 62. Even in these cases, substantially the same effect as in the case of using CFC as the solvent 62 can be obtained.

In the present embodiment, the case is described in which the coating film 53 and the formation method thereof are applied to the coating film 43 of the earth electrode 41 that is a member for a plasma processing apparatus. The coating film 53 and the formation method thereof of the present embodiment can also be applied to a coating film of a member for a plasma processing apparatus other than the earth electrode 41. The member for a plasma processing apparatus to which the coating film 53 and the formation method thereof of the present embodiment is disposed in the processing chamber 3 of the plasma processing apparatus 1, and a coating film of the member for a plasma processing apparatus is exposed to the plasma 4 when the plasma processing apparatus is in operation.

### Embodiment 2

In Embodiment 2, the coating film 53 is formed by the suspension plasma spraying method as in Embodiment 1, but the solvent 62 contained in the suspension liquid 63 is different from that in Embodiment 1. In Embodiment 2, an ammonium fluoride (NH₄F) aqueous solution is used as the solvent 62. The solvent 62 containing fluorine is common to Embodiment 1 and Embodiment 2. A step of forming the coating film 53 using the suspension plasma spraying method in Embodiment 2 will be described below with reference to FIG. 2.

The thermal spraying material 61 and the solvent 62 are placed in a stirrer (not illustrated) and stirred to produce the suspension liquid 63. The thermal spraying material 61 used in Embodiment 2 is the same as that in Embodiment 1.

The solvent 62 used in Embodiment 2 is the ammonium fluoride (NH₄F) aqueous solution. A concentration of the ammonium fluoride aqueous solution forming the solvent 62 is preferably 5% by weight or more and 50% by weight or less. This is because when the concentration of the ammonium fluoride aqueous solution is more than 50% by weight, it is difficult to produce the appropriate suspension liquid 63, and NH₄F is precipitated in the suspension liquid 63 with the thermal spraying material 61 as a nucleus. On the other hand, when the concentration of the ammonium fluoride aqueous solution is less than 5% by weight, a fluorine content of the solvent 62 decreases, and an effect of reducing the ratio of yttrium oxide in the coating film 53 formed by the suspension plasma spraying method decreases.

In Embodiment 2, the suspension liquid 63 produced by using the thermal spraying material 61 similar to that in Embodiment 1 and the solvent 62 made of the ammonium fluoride aqueous solution is introduced into the suspension liquid supply pipe 75 in the same manner as in Embodiment 1, is caused to pass through the suspension liquid supply pipe 75, and is put into the thermal spraying flame 74. The suspension liquid 63 put into the thermal spraying flame 74 is heated by the thermal spraying flame 74. Accordingly, the solvent 62 contained in the suspension liquid 63 is volatilized, and the yttrium fluoride particles and the yttrium oxyfluoride particles contained in the suspension liquid 63 are in a molten state. At this time, a part of yttrium fluoride and a part of yttrium oxyfluoride are thermally decomposed into yttrium ions, fluorine ions, and oxygen ions. Then, when the thermally decomposed yttrium fluoride and yttrium oxyfluoride are recombined, yttrium fluoride, yttrium oxyfluoride, and yttrium oxide are formed, and are thermally sprayed onto the base material 52.

In the suspension plasma spraying method in Embodiment 2, the ammonium fluoride aqueous solution is used as the solvent 62 contained in the suspension liquid 63. Therefore, in the thermal spraying flame 74, oxygen in the atmosphere, oxygen generated from yttrium oxyfluoride, and oxygen generated from the solvent 62 exist around a material melt (melt of the thermal spraying material 61). However, fluorine generated from yttrium fluoride, fluorine generated from yttrium oxyfluoride, and fluorine generated from ammonium fluoride forming the solvent 62 also exist around the material melt. Electronegativity of fluorine is larger than electronegativity of oxygen. Therefore, when yttrium fluoride and yttrium oxyfluoride that are thermally decomposed in the thermal spraying flame 74 are recombined, a probability of yttrium oxyfluoride being formed again is higher than a probability of yttrium oxide being formed. As a result, it is possible to reduce the probability of yttrium oxide being formed when yttrium fluoride and yttrium oxyfluoride that are thermally decomposed in the thermal spraying flame 74 are recombined. Therefore, as compared with a case in which water or an organic solvent is used as the solvent 62, yttrium oxide can be prevented from being formed in the thermal spraying flame 74 when a solvent (here, ammonium fluoride aqueous solution) containing fluorine is used as the solvent 62 as in Embodiment 2.

The melted yttrium fluoride, the melted yttrium oxyfluoride, and the melted yttrium oxide are thermally sprayed onto and adhere to the base material 52, and are cooled and solidified. Accordingly, a mixed film of yttrium fluoride crystals, yttrium oxyfluoride crystals, and yttrium oxide crystals is formed on the base material 52. This operation is repeated to stack the mixed films, thereby forming the coating film 53 having a thickness of, for example, about 100 μm. The coating film 53 is made of a mixture of yttrium fluoride, yttrium oxyfluoride, and yttrium oxide.

Ratios of crystal phases contained in the coating film 53 formed by the suspension plasma spraying method of Embodiment 2 are 2% by weight for an orthorhombic crystal YF₃ phase, 3% by weight for a hexagonal crystal YF₃ phase, 53% by weight for an orthorhombic crystal Y₅O₄F₇ phase, 39% by weight for a hexagonal crystal Y—O—F phase, and 3% by weight for a monoclinic crystal Y₂O₃ phase. The crystal phase ratios are determined by the same method as in Embodiment 1.

Therefore, it is confirmed that the ratios of the yttrium oxide phases in the coating film 53 can be reduced when the coating film 53 is formed by the suspension plasma spraying method using the ammonium fluoride aqueous solution as the solvent 62 as in Embodiment 2, compared with the case in which the coating film 53 is formed by the suspension plasma spraying method using water or an organic solvent as the solvent 62.

As in Embodiment 2, the SEM image of the cross section of the coating film 53 when the coating film 53 is formed by the suspension plasma spraying method using the ammonium fluoride aqueous solution as the solvent 62 is similar to the SEM image in FIG. 3. That is, in the SEM image of the coating film 53 in Embodiment 2, it is confirmed that a generation amount of the bright region (white region) 209 made of yttrium oxide is clearly reduced as compared with that of the SEM image in FIG. 4. It is also confirmed that the crystallite size of the surface of the coating film 53 in Embodiment 2 is 30 nm or less from an XRD analysis of the coating film 53. By observation of the cross section STEM, in the coating film 53 in Embodiment 2, it can be determined that a microcrystalline layer is formed in a region from the surface of the coating film 53 to a depth of 10 μm. In addition, when considered together with the XRD analysis results, it is possible to estimate that the thickness of the microcrystalline layer having a crystallite size of 30 nm or less is 10 μm or more.

As described in Embodiment 1 as well, reducing the number of remaining particle portions 211 in the coating film 53 and thickening the microcrystalline layer on the surface of the coating film 53 lead to extending the life of the coating film 53. Also in Embodiment 2, it is possible to suppress or prevent the remaining particle portion 211 from being generated in the coating film 53. Further, the microcrystalline layer on the surface of the coating film 53 can be thickened. As a result, the life of the coating film 53 can be extended.

As described above, according to Embodiment 2, it is possible to form the coating film 53 having low contents of the yttrium oxide phases. Further, the coating film 53 having a thick surface microcrystalline layer whose average crystallite size is 30 nm or less on the surface can be formed. In the processing chamber 3 of the plasma processing apparatus 1 in which a member (here, the earth electrode 41) including the coating film 53 is disposed, the generation of the particles from the surface of the coating film 53 is reduced, and the life of the coating film 53 can be extended.

In Embodiment 2, the ammonium fluoride aqueous solution is used as the solvent 62. As the solvent 62, a potassium fluoride (KF) aqueous solution may be used instead of the ammonium fluoride aqueous solution. Even when the potassium fluoride aqueous solution is used as the solvent 62, substantially the same effect as when the ammonium fluoride aqueous solution is used as the solvent 62 can be obtained. When the potassium fluoride aqueous solution is used as the solvent 62, a concentration of the potassium fluoride aqueous solution is preferably 5% by weight or more and 50% by weight or less, similarly to the concentration range of the ammonium fluoride aqueous solution described above.

In Embodiment 2, a sodium fluoride (NaF₂) aqueous solution may be used as the solvent 62. When it is necessary to use an aqueous solution with a concentration of less than 5% by weight, a high effect can be obtained by using the sodium fluoride (NaF₂) aqueous solution because the fluorine concentration in the solvent is high. However, the concentration of the sodium fluoride aqueous solution is preferably 4% by weight or less. This is because sodium fluoride is precipitated in the suspension liquid 63 with thermal spraying material 61 as a nucleus when the concentration of the sodium fluoride aqueous solution is more than 4% by weight.

Accordingly, in Embodiment 2, as the solvent 62, any one of an ammonium fluoride aqueous solution, a potassium fluoride aqueous solution, and a sodium fluoride aqueous solution, or a mixed liquid of two or more of an ammonium fluoride aqueous solution, a potassium fluoride aqueous solution, and a sodium fluoride aqueous solution can be used.

Although the invention has been specifically described based on the embodiments, the invention is not limited to the embodiments, and various modifications can be made without departing from the gist of the invention.

### REFERENCE SIGNS LIST

1: plasma processing apparatus
2: vacuum container
3: processing chamber
4: plasma
5: stage
6: wafer
7: exhaust port
8: space
9: exhaust plate
11: high-frequency power supply
12: impedance matching machine
13: window member
14: shower plate
15: through hole
16: gap
17: processing gas supply pipe
18: valve
21: pressure adjustment plate
22: turbo molecular pump
23: dry pump
24: valve
25: pressure detector
27: exhaust pipe
28, 29: valve
31: waveguide tube
31a: rectangular waveguide tube portion
31b: circular waveguide tube portion
31c: hollow portion
32: magnetron oscillator
33, 34: solenoid coil
41: earth electrode
42: base material
43: coating film
52: base material
53: coating film
61: thermal spraying material
62: solvent
63: suspension liquid
71: nozzle
72: high voltage
73: plasma gas
74: thermal spraying flame

1. A method for manufacturing a member for a plasma processing apparatus, the method comprising:
(a) a step of preparing a base material used for the member for a plasma processing apparatus;
(b) a step of preparing a first suspension liquid containing a fluorine-containing solvent, a plurality of yttrium fluoride particles, and a plurality of yttrium oxyfluoride particles; and
(c) a step of forming a coating film on the base material by a suspension plasma spraying method using the first suspension liquid.

2. The method for manufacturing a member for a plasma processing apparatus according to claim 1, wherein
the solvent is a fluorocarbon liquid.

3. The method for manufacturing a member for a plasma processing apparatus according to claim 1, wherein
the solvent is made of any one of CFC, FC, HCFC, or HFC, or is made of a mixed liquid of two or more of CFC, FC, HCFC, and HFC.

4. The method for manufacturing a member for a plasma processing apparatus according to claim 1, wherein
the solvent is made of any one of an ammonium fluoride aqueous solution, a potassium fluoride aqueous solution, or a sodium fluoride aqueous solution, or is made of a mixed liquid of two or more of the ammonium fluoride aqueous solution, the potassium fluoride aqueous solution, and the sodium fluoride aqueous solution.

5. The method for manufacturing a member for a plasma processing apparatus according to claim 4, wherein
the ammonium fluoride aqueous solution and the potassium fluoride aqueous solution each have a concentration of 5% by weight or more and 50% by weight or less.

6. The method for manufacturing a member for a plasma processing apparatus according to claim 4, wherein
a concentration of the sodium fluoride aqueous solution is 4% by weight or less.

7. The method for manufacturing a member for a plasma processing apparatus according to claim 1, wherein
an average particle diameter of the plurality of yttrium fluoride particles and an average particle diameter of the plurality of yttrium oxyfluoride particles each are 0.05 μm or more and 50 μm or less.

8. The method for manufacturing a member for a plasma processing apparatus according to claim 1, wherein
the member for a plasma processing apparatus is disposed in a processing chamber of a plasma processing apparatus, and
the coating film is exposed to plasma when the plasma processing apparatus is in operation.

9. The method for manufacturing a member for a plasma processing apparatus according to claim 1, wherein
a content of yttrium oxide in the coating film is 9% by weight or less.

10. The method for manufacturing a member for a plasma processing apparatus according to claim 1, wherein
a content of yttrium oxide in the coating film is 5% by weight or less.

11. The method for manufacturing a member for a plasma processing apparatus according to claim 1, wherein
the coating film includes an yttrium fluoride phase and an yttrium oxyfluoride phase, and
an average size of crystallites in the yttrium fluoride phase and an average size of crystallites in the yttrium oxyfluoride phase are each 50 nm or less.

12. A member for a plasma processing apparatus, the member comprising:
a base material; and
a coating film formed on the base material, wherein
the coating film includes an yttrium fluoride phase and an yttrium oxyfluoride phase,
an average size of crystallites in the yttrium fluoride phase and an average size of crystallites in the yttrium fluoride phase are each 50 nm or less, and
a content of yttrium oxide in the coating film is 5% by weight or less.

13. The member for a plasma processing apparatus according to claim 12, wherein
the coating film is formed by a suspension plasma spraying method.

14. The member for a plasma processing apparatus according to claim 12, wherein
the member for a plasma processing apparatus is disposed in a processing chamber of a plasma processing apparatus and is exposed to plasma when the plasma processing apparatus is in operation.
